(19) United States
(12) Patent Application Publication
(10) Pub. No.: US 2026/0182165 A1
(43) Pub. Date: Jun. 25, 2026

(54) DISPLAY DEVICE AND ELECTRONIC DEVICE INCLUDING THE SAME

(71) Applicant: Samsung Display Co., LTD., Yongin-si (KR)

(72) Inventors: KEUNYOUNG PARK, Yongin-si (KR); SEUNG JUN YU, Yongin-si (KR)

(21) Appl. No.: 19/366,937

(22) Filed: Oct. 23, 2025

(30) Foreign Application Priority Data
Dec. 20, 2024 (KR) 10-2024-0192136
Jan. 7, 2025 (KR) 10-2025-0002330
Apr. 9, 2025 (KR) 10-2025-0046337

(51) Int. Cl. H10K 59/124; H10K 59/80; H10K 102/00

(52) U.S. Cl. CPC H10K 59/124; H10K 59/80515; H10K 59/80521; H10K 2102/351

(57) ABSTRACT

A display device includes a base layer, insulating layers disposed above the base layer, conductive patterns disposed above the base layer, and a capacitor disposed above the base layer. The insulating layers includes a first insulating layer including an organic material, a second insulating layer including an organic material, and a third insulating layer including an inorganic material. The capacitor includes a first electrode disposed between the first and second insulating layers, a second electrode disposed between the second and third insulating layers, and a third electrode disposed on the third insulating layer, where all of the first, second, and third electrodes overlap one another in a plan view. The second insulating layer provides a flat upper surface to the second electrode by filling a contact hole formed in the first insulating layer.

This application claims priority to Korean Patent Application No. 10-2024-0192136, filed on Dec. 20, 2024, Korean Patent Application No. 10-2025-0002330, filed on Jan. 7, 2025, and Korean Patent Application No. 10-2025-0046337, filed on Apr. 9, 2025, and all the benefits accruing therefrom under 35 U.S.C. § 119, the contents of which in their entireties are herein incorporated by reference.

### BACKGROUND

### (1) Field

The present disclosure herein relates to a display device and an electronic device including the display device, and more particularly, to an ultra-high resolution display device and an electronic device including the display device.

### (2) Description of the Related Art

Multimedia electronic devices, such as a television, a mobile phone, a tablet computer, a navigation system, and a game console, are equipped with a display device that displays images. Recently, various electronic devices for implementing augmented reality (AR), virtual reality (VR), mixed reality (MR), and extended reality (XR) are being developed. Such electronic devices may be desired to include a high-resolution display device.

### SUMMARY

The present disclosure provides a display device having an ultra-high resolution.

The present disclosure also provides an electronic device including the display device having an ultra-high resolution.

An embodiment of the invention provides a display device including a base layer, a plurality of insulating layers disposed above the base layer, a plurality of conductive patterns disposed above the base layer, a capacitor disposed above the base layer, a transistor disposed above the base layer, and a light-emitting element disposed above the base layer. In such an embodiment, the plurality of insulating layers include a first insulating layer including an organic material, a second insulating layer disposed on the first insulating layer and including an organic material, and a third insulating layer disposed on the second insulating layer and including an inorganic material. In such an embodiment, the capacitor includes a first electrode disposed between the first insulating layer and the second insulating layer and connected to a pattern disposed below the first insulating layer through a first contact region defined through the first insulating layer, a second electrode disposed between the second insulating layer and the third insulating layer and connected to the first electrode through a second contact region exposing a contact portion of the first electrode, and a third electrode disposed on the third insulating layer, facing the second electrode, and overlapping the first contact region and not overlapping the second contact region in a plan view. In such an embodiment, in the plan view, the first contact region and the second contact region do not overlap each other, and the second insulating layer fills the first contact region.

In an embodiment, the first electrode may include a first edge and a second edge which are opposite to each other in a first direction. In such an embodiment, in the plan view, each of the second contact region and the first contact region may be closer to the first edge than to the second edge, and in the plan view, a distance between the second contact region and the first edge may be shorter than a distance between the first contact region and the first edge.

In an embodiment, in the plan view, the third electrode may be disposed inside the second electrode.

In an embodiment, the second electrode may have a thickness smaller than a thickness of the first electrode.

In an embodiment, the first electrode and the second electrode may have substantially a same planar area as each other.

In an embodiment, the second electrode may include a first edge and a second edge which are opposite to each other in a first direction, the second contact region may extend in a second direction orthogonal to the first direction, and a length of the second contact region in the second direction may be greater than a length of the second electrode in the second direction.

In an embodiment, the organic material of the second insulating layer may include at least one selected from a photosensitive polyimide (PSPI)-based resin, a polysiloxane-based resin, a polyhedral oligomeric silsesquioxanes (POSS)-based resin, or an acrylic-based resin.

In an embodiment, the first electrode may include a first edge and a second edge which are opposite to each other in a first direction, and the second insulating layer may include a first portion and a second portion, which face each other in the first direction, with the second contact region interposed therebetween.

In an embodiment, the second electrode may include a first edge and a second edge which are opposite to each other in a first direction, the second insulating layer may include an inclined surface inclined from the second edge toward an upper surface of the first insulating layer, and the third insulating layer may cover the second edge of the second electrode, the inclined surface, and the upper surface of the first insulating layer.

In an embodiment, the first electrode may include a first edge and a second edge which are opposite to each other in a first direction, and the pattern may include a first conductive pattern among the plurality of conductive patterns. In such an embodiment, the plurality of conductive patterns may include a second conductive pattern spaced apart from the first edge of the first electrode and a third conductive pattern spaced apart from the second edge of the first electrode. In such an embodiment, the second insulating layer may overlap the second conductive pattern and the third conductive pattern in the plan view.

In an embodiment, the second contact region may expose the first edge of the first electrode, and the second electrode may cover the contact portion and the first edge of the first electrode and contact an upper surface of the first insulating layer.

In an embodiment, the second contact region may expose a portion of an upper surface of the first insulating layer, and the third insulating layer may contact the portion of the upper surface of the first insulating layer through the second contact region.

In an embodiment, a portion of the second insulating layer may be disposed between the first electrode and the third conductive pattern, and a portion of the second electrode may be disposed on the second insulating layer in a region between the first electrode and the third conductive pattern.

In an embodiment, the third insulating layer may be disposed on the portion of the second electrode and the portion of the second insulating layer. In such an embodiment, a portion of the third electrode may be disposed on the portion of the second electrode.

In an embodiment, the transistor may output a data voltage to the capacitor.

In an embodiment, the third insulating layer may have a thickness smaller than the first insulating layer and the second insulating layer.

In an embodiment of the invention, an electronic device includes a display device and a processor which controls the display device. In such an embodiment, the display device includes a base layer, a plurality of insulating layers disposed above the base layer, a plurality of conductive patterns disposed above the base layer, a capacitor disposed above the base layer, a transistor disposed above the base layer, and a light-emitting element disposed above the base layer. In such an embodiment, the plurality of insulating layers include a first insulating layer including an organic material, a second insulating layer disposed on the first insulating layer and including an organic material, and a third insulating layer disposed on the second insulating layer and including an inorganic material. In such an embodiment, the capacitor includes a first electrode disposed between the first insulating layer and the second insulating layer and connected to a pattern disposed below the first insulating layer among the plurality of conductive patterns through a first contact region defined through the first insulating layer, a second electrode disposed between the second insulating layer and the third insulating layer and connected to the first electrode through a second contact region exposing a contact portion of the first electrode, and a third electrode disposed on the third insulating layer, facing the second electrode, and overlapping the first contact region and not overlapping the second contact region in a plan view. In such an embodiment, in the plan view, the first contact region and the second contact region do not overlap each other, and the second insulating layer fills the first contact region.

In an embodiment, the electronic device may be a virtual reality (VR) device.

In an embodiment, the second electrode may have a thickness smaller than a thickness of the first electrode, and the third insulating layer may have a thickness smaller than a thickness of the first insulating layer and a thickness of the second insulating layer.

In an embodiment, the organic material of the second insulating layer may include at least one selected from a photosensitive polyimide (PSPI)-based resin, a polysiloxane-based resin, a polyhedral oligomeric silsesquioxanes (POSS)-based resin, or an acrylic-based resin.

In an embodiment, the first electrode may include a first edge and a second edge which are opposite to each other in a first direction, and the pattern connected to the first electrode may include a first conductive pattern among the plurality of conductive patterns. In such an embodiment, the plurality of conductive patterns may include a second conductive pattern spaced apart from the first edge of the first electrode and a third conductive pattern spaced apart from the second edge of the first electrode. In such an embodiment, the second insulating layer may overlap the second conductive pattern and the third conductive pattern, the second contact region may expose the first edge of the first electrode, and the second electrode may cover the contact portion and the first edge of the first electrode and come in contact with an upper surface of the first insulating layer.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a block diagram of an electronic device according to an embodiment of the invention;

FIG. 2 illustrates schematic diagrams of electronic devices according to embodiments of the invention;

FIG. 3 is an exploded perspective view of a virtual reality (VR) device according to an embodiment of the invention;

FIG. 4 is a perspective view of a display panel according to an embodiment of the invention;

FIGS. 5A to 5C are equivalent circuits of a pixel according to an embodiment of the invention;

FIG. 6 is a cross-sectional view of the display panel according to an embodiment of the invention;

FIG. 7 is a plan view of a first capacitor according to an embodiment of the invention;

FIG. 8 is a cross-sectional view of the first capacitor according to an embodiment of the invention;

FIGS. 9 and 10 are plan views of the first capacitor according to an embodiment of the invention;

FIG. 11 is a plan view of the first capacitor according to an embodiment of the invention; and

FIG. 12 is a cross-sectional view of the first capacitor according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. In this specification, it will be understood that when an element (or region, layer, portion, etc.) is referred to as being “connected to” or “coupled to” another element, it can be directly connected or coupled to the other element, or intervening elements may be present.

Like reference numerals refer to like elements throughout. In addition, in the drawings, the thicknesses, ratios, and dimensions of elements are exaggerated for effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

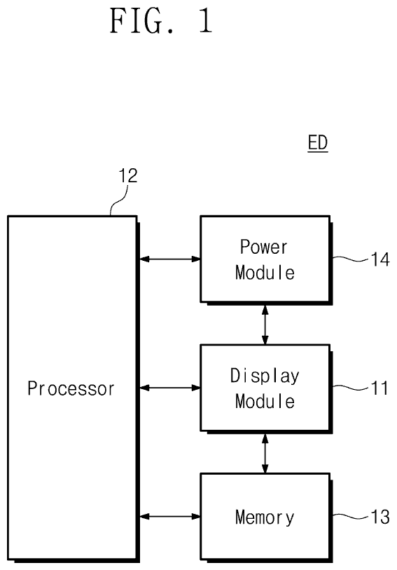

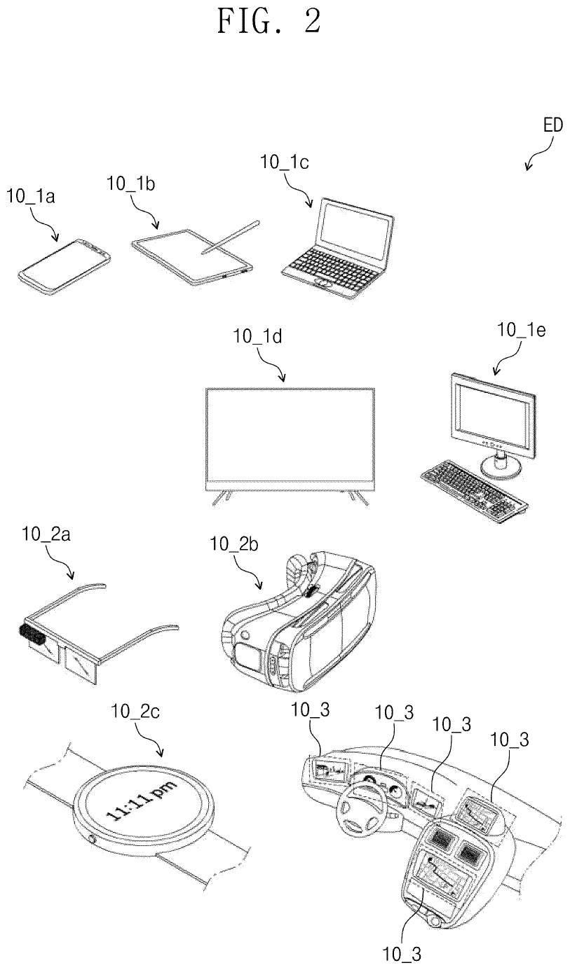

FIG. 1 is a block diagram of an electronic device ED according to an embodiment of the invention. FIG. 2 illustrates schematic diagrams of electronic devices ED according to an embodiment of the invention.

Referring to FIG. 1, the electronic device ED according to an embodiment of the invention may include a display device 11, a processor 12, a memory 13, and a power module 14.

The processor 12 may include at least one selected from a central processing unit (CPU), an application processor (AP), a graphic processing unit (GPU), a communication processor CP, an image signal processor (ISP), or a controller.

The memory 13 may store data information used for the operation of the processor 12 or the display device 11. When the processor 12 executes an application stored in the memory 13, an image data signal and/or an input control signal may be transmitted to the display device 11, and the display device 11 may process the received signal and output image information through a display screen.

The power module 14 may include a power supply module, such as a power adapter or a battery device, and a power conversion module configured to convert power supplied by the power supply module and generate power for the operation of the electronic device ED.

The processor 12, the power module 14, and the memory 13, which are described above, may be included in the display device 11, or may be separated from the display device 11 as a separate module. The processor 12, the power module 14, and the memory 13 may be disposed in a form separated from the display device 11 inside a housing forming the exterior of the electronic device ED.

Referring to FIG. 2, the electronic device ED according to an embodiment of the invention may include not only typical information-providing electronic devices such as a smartphone 10_1a, a tablet personal computer (PC) 10_1b, a laptop computer 10_1c, a television (TV) 10_1d, and a desktop monitor 10_1e, but also wearable electronic devices such as smart glasses 10_2a, a head-mounted display device 10_2b, and a smart watch 10_2c, as well as automotive electronic devices 10_3 such as a center information display (CID) disposed on a vehicle's instrument panel, center fascia, or dashboard, and a room mirror display. The display device 11 included in such an electronic device ED may be described as a display device DD hereinafter.

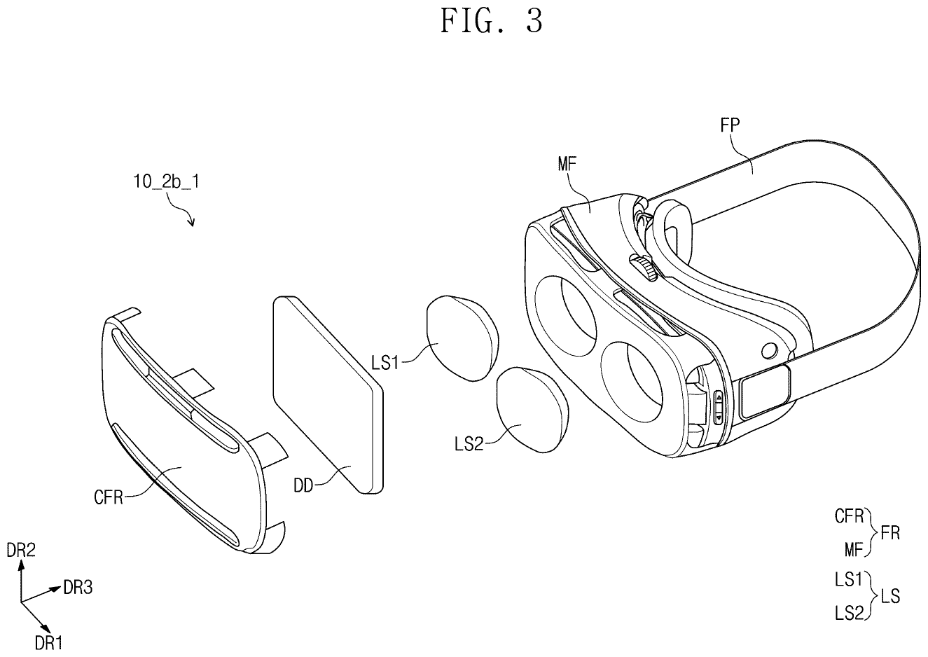

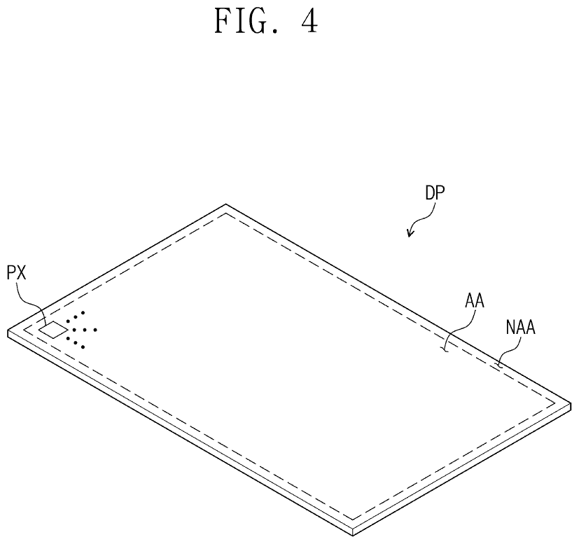

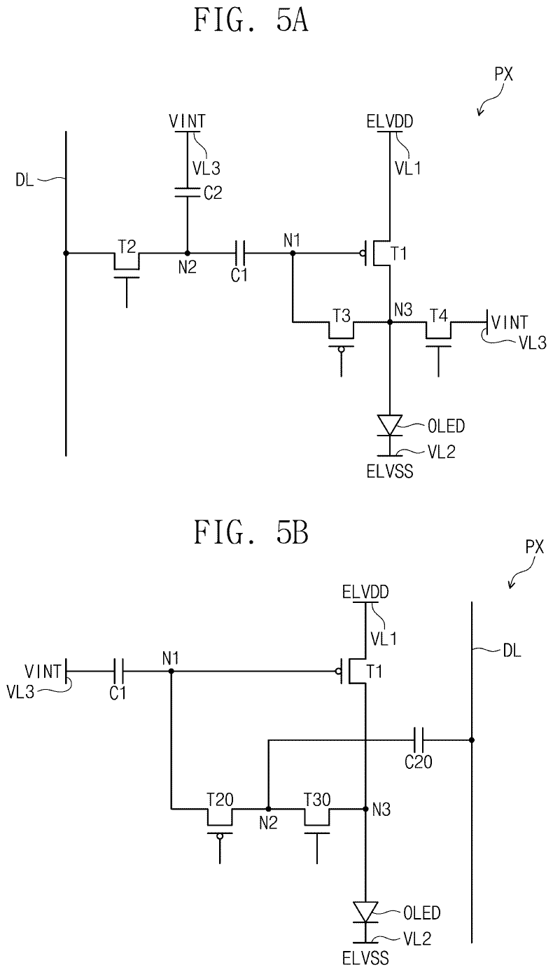

FIG. 3 is an exploded perspective view of a virtual reality device 10_2b_1 according to an embodiment of the invention.

An embodiment of the virtual reality device 10_2b_1 of FIG. 3 may be the head-mounted display device 10_2b illustrated in FIG. 2. The virtual reality device 10_2b_1 of FIG. 3 may be a see-closed type that provides virtual reality (VR) to a user with a screen independent of external objects.

Referring to FIG. 3, an embodiment of the virtual reality device 10_2b_1 may include a display device DD and a lens LS facing the display device DD. In addition, the virtual reality device 10_2b_1 may include a frame FR (or housing) configured to accommodate the display device DD and the lens LS. The frame FR may include a main frame MF and a cover frame CFR. A fixing member FP may be coupled to the main frame MF and worn on a user's head.

The cover frame CFR may be coupled to the main frame MF, and the lens LS and the display device DD may be disposed in a space between them. The main frame MF may provide a space for accommodating the lens LS and the display device DD.

In a state in which a user wears a virtual reality device 10_2b_1, the lens LS may be positioned between the display device DD and the user. The lens LS may allow an image generated by the display device DD to pass through and provide the image to the user. In an embodiment, for example, the lens LS may include various types of lenses such as a multi-channel lens, a convex lens, a concave lens, a spherical lens, an aspherical lens, a single lens, a compound lens, a standard lens, a narrow-angle lens, a wide-angle lens, a fixed-focus lens, and a variable-focus lens. The lens LS may include a first lens LS1 and a second lens LS2. The first lens LS1 and the second lens LS2 may be disposed to correspond to the positions of the user's left and right eyes. The display device DD may be coupled to the main frame MF in a fixed state or in a detachable state.

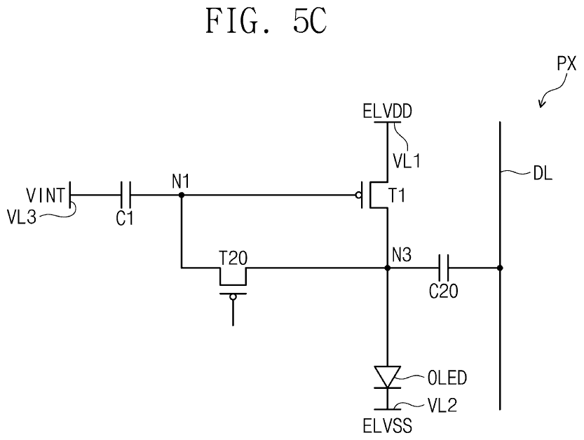

FIG. 4 is a perspective view of a display panel DP according to an embodiment of the invention. FIGS. 5A to 5C are equivalent circuits of a pixel PX according to an embodiment of the invention.

An embodiment of the display device DD described with reference to FIG. 3 includes a display panel DP. Referring to FIG. 4, an embodiment of the display panel DP may include a display region AA and a peripheral region NAA. The peripheral region NAA may surround the display region AA in a plan view or when viewed in a thickness direction of the display panel DP. Pixels PX may be disposed in the display region AA, and pixels PX may not be disposed in the peripheral region NAA. Each of the pixels PX may include a light-emitting element and a pixel driving circuit configured to control the light-emitting element. As resolution increases, the area of a region (hereinafter referred to as a pixel region) in which the pixel driving circuit of each pixel PX is disposed decreases.

In an embodiment, the pixel PX may have any one of the equivalent circuits illustrated in FIGS. 5A to 5C. The pixel driving circuit may commonly include a driving transistor T1, a switching transistor T2 or T20, and a first capacitor C1.

Referring to FIG. 5A, in an embodiment, the pixel driving circuit may include first to fourth transistors T1 to T4, a first capacitor C1, and a second capacitor C2. In an embodiment, as shown in FIG. 5A, the first and third transistors T1 and T3 may be P-type transistors, and the second and fourth transistors T2 and T4 may be N-type transistors, but the embodiment of the invention is not limited thereto.

In such an embodiment, the first transistor T1 may be a driving transistor, and the second transistor T2 may be a switching transistor. The first transistor T1 is electrically connected between a light-emitting element OLED and a first voltage line VL1 which is connected to receive a first power supply voltage ELVDD. The light-emitting element OLED is electrically connected between a third node N3 and a second voltage line VL2 which is connected to receive a second power supply voltage ELVSS.

The second transistor T2 is electrically connected between a data line and a second node N2 and outputs a data signal. The first capacitor C1 is electrically connected between the source of the second transistor T2 and the gate of the first transistor T1, that is, between the second node N2 and a first node N1. The second capacitor C2 is electrically connected between the second node N2 and a third voltage line VL3 configured to receive a reference voltage VINT.

The third transistor T3 is electrically connected between the gate and the drain of the first transistor T1, that is, between the first node N1 and the third node N3. The fourth transistor T4 is electrically connected between the third node N3 and the third voltage line VL3 which is connected to receive the reference voltage VINT. The fourth transistor T4 may initialize the light-emitting element OLED to the reference voltage VINT. During a period in which the third transistor T3 and the fourth transistor T4 are simultaneously turned on, the first capacitor C1 may also be initialized to the reference voltage VINT.

Referring to FIG. 5B, in another embodiment, the pixel driving circuit may include first, second, and third transistors T1, T20, and T30, a first capacitor C1, and a second capacitor C20. In an embodiment, as shown in FIG. 5B, the first and second transistors T1 and T20 may be P-type transistors, and the third transistor T30 may be an N-type transistor, but the embodiment of the invention is not limited thereto.

The first transistor T1 is electrically connected between the light-emitting element OLED and the first voltage line VL1 which is connected to receive the first power supply voltage ELVDD. The light-emitting element OLED is electrically connected to the second voltage line VL2 which is connected to receive the second power supply voltage ELVSS.

The second transistor T20 is electrically connected between the gate of the first transistor T1 and the source of the third transistor T30, that is, between the first node N1 and the second node N2. The third transistor T30 is electrically connected between the second node N2 and the third node N3.

The first capacitor C1 is electrically connected between the first node N1 and the third voltage line VL3 which is connected to receive the reference voltage VINT. The second capacitor C2 is electrically connected between the second node N2 and the data line DL. An electrode connected to the data line DL of the second capacitor C2 may be configured as or defined by a portion of the data line DL.

In another embodiment, as illustrated in FIG. 5C, the third transistor T30 of FIG. 5B may be omitted. In such an embodiment, the second transistor T20 is directly connected to the third node N3.

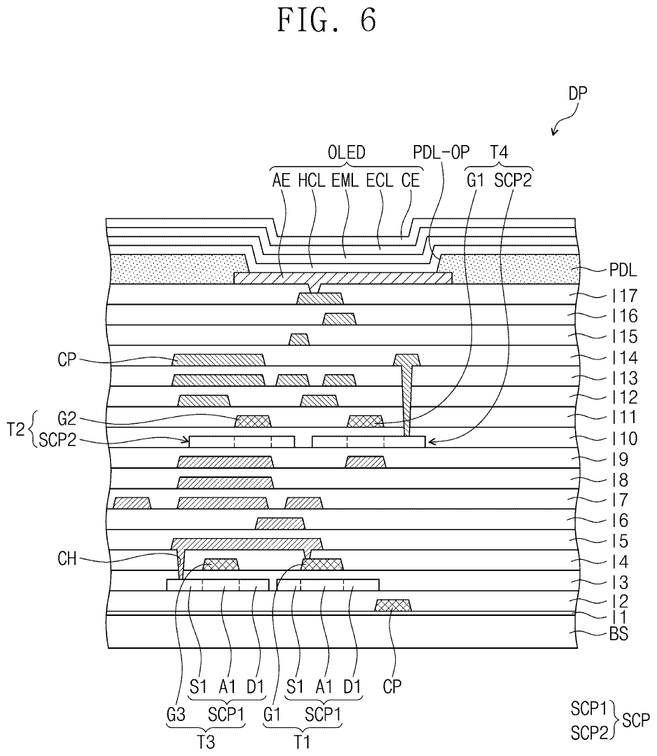

FIG. 6 is a cross-sectional view of the display panel DP according to an embodiment of the invention. FIG. 6 is illustrated based on the pixel PX of FIG. 5A.

In an embodiment, the display panel DP includes a plurality of insulating layers I1 to I17 and a plurality of patterns SCP and CP disposed above a base layer BS. FIG. 6 illustrates an embodiment where seventeen insulating layers I1 to I17 are provided as an example. Each of the seventeen insulating layers I1 to I17 may include an inorganic material or an organic material. The plurality of patterns SCP and CP may include semiconductor patterns SCP and conductive patterns CP. The semiconductor patterns SCP form a transistor, and the conductive patterns CP form a signal line or a circuit element.

The seventeen insulating layers I1 to I17 electrically insulate the semiconductor patterns SCP and the conductive patterns CP from each other in the thickness direction of the display panel DP and positionally separate them from each other (i.e., physically separate them from each other).

A semiconductor pattern SCP1 of the first transistor T1 and a semiconductor pattern SCP1 of the third transistor T3 may be disposed on a second insulating layer I2. Each of the semiconductor patterns SCP1 may include low-temperature polysilicon. Each of the semiconductor patterns SCP1 may include a source region S1, a channel region A1 (or active region), and a drain region D1. Each of the source region S1 and the drain region D1 is a doped region and has greater conductivity than the channel region A1. A gate G1 (or gate electrode) of the first transistor T1 is disposed above the semiconductor pattern SCP1 of the first transistor T1. A gate G3 of the third transistor T3 is disposed above the semiconductor pattern SCP1 of the third transistor T3.

One of the conductive patterns CP may electrically connect the gate G1 of the first transistor T1 and the source region S1 of the third transistor T3 to each other. The embodiment of the invention is not limited thereto. In an embodiment of the invention, one conductive pattern CP may connect the gate G1 of the first transistor T1 and the drain region D1 of the third transistor T3 to each other.

FIG. 6 illustrates an embodiment in which a conductive pattern CP disposed on a fourth insulating layer I4 is connected to the gate G1 of the first transistor T1 through a contact hole CH defined through the fourth insulating layer I4 and is connected to the source region S1 of the third transistor T3 through a contact hole CH defined through a third insulating layer I3 and the fourth insulating layer I4 as an example. In addition, the plurality of patterns SCP and CP disposed in (or directly on) different layers, respectively, may be connected to each other through a contact hole defined through at least one insulating layer disposed between the patterns.

A semiconductor pattern SCP2 of the second transistor T2 and a semiconductor pattern SCP2 of the fourth transistor T4 may be disposed on a ninth insulating layer I9. Each of the semiconductor patterns SCP2 may include a metal oxide semiconductor. A gate G2 of the second transistor T2 is disposed above the semiconductor pattern SCP2 of the second transistor T2, and a gate G4 of the fourth transistor T4 is disposed above the semiconductor pattern SCP2 of the fourth transistor T4.

In such an embodiment, each of the semiconductor patterns SCP1 may include low-temperature polysilicon, and each of the semiconductor patterns SCP2 may include a metal oxide semiconductor, but the embodiment of the invention is not limited thereto. In an embodiment of the invention, the semiconductor patterns SCP1 may include a metal oxide semiconductor different from that of the semiconductor patterns SCP2.

A pixel defining layer PDL and a light-emitting element OLED are disposed on a seventeenth insulating layer I17. The light-emitting element OLED may include a first electrode AE, a hole control layer HCL, a light-emitting layer EL, an electron control layer ECL, and a second electrode CE. In this embodiment, the first electrode AE may be an anode, and the second electrode CE may be a cathode.

As resolution increases, the area occupied by a pixel PX on a plane (i.e., in a plan view or when viewed in a thickness direction) is reduced, and circuit elements inevitably have to be stacked in the thickness direction of the display panel DP. The areas occupied by the capacitors C1, C2, and C20 described with reference to FIGS. 5A to 5C may also be reduced.

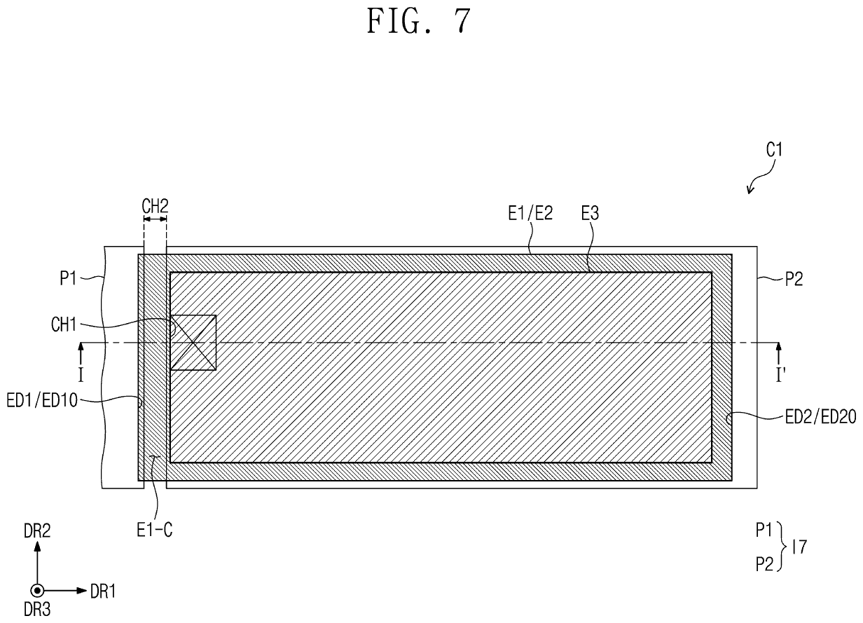

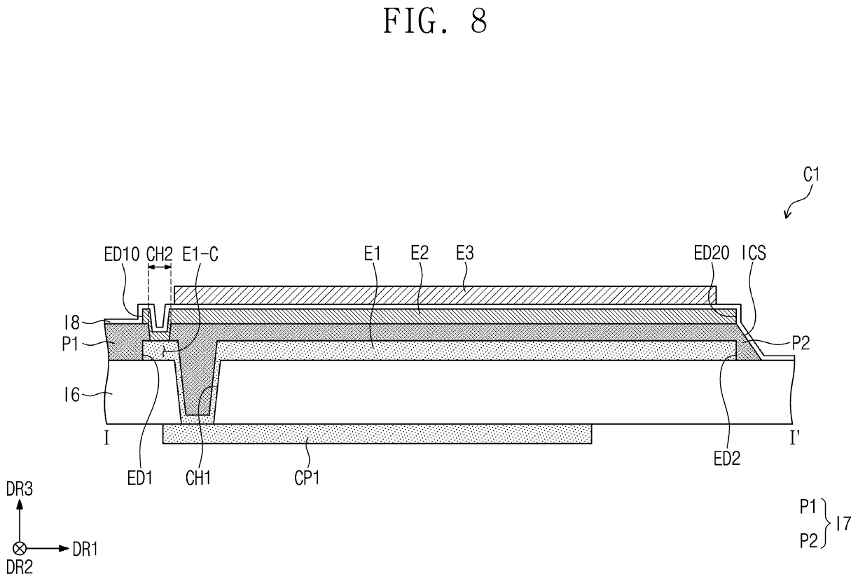

FIG. 7 is a plan view of the first capacitor C1 according to an embodiment of the invention. FIG. 8 is a cross-sectional view of the first capacitor C1 according to an embodiment of the invention.

In an embodiment, the first capacitor C1 described in FIGS. 7 and 8 includes three conductive patterns CP disposed between the sixth insulating layer I6 and the ninth insulating layer I9 of FIG. 6. The first capacitor C1 may include the conductive patterns CP disposed in (or directly on) different layers of FIG. 6, respectively, and the description of the first capacitor C1 to be described later may be equally applied to the second capacitors C2 and C20 described with reference to FIGS. 5A to 5C.

In addition, the terms “sixth insulating layer I6” to “ninth insulating layer I9” are used merely to distinguish the seventeen insulating layers I1 to I17 illustrated in FIG. 6 from each other, and at least three insulating layers are associated with the first capacitor C1. Accordingly, the terms “first to third insulating layers” may be used to distinguish the three insulating layers from each other. The three insulating layers may be referred to as a lower insulating layer, a middle insulating layer, and an upper insulating layer. Likewise, the terms “first to third electrodes” may be used to distinguish the three conductive patterns CP from each other.

The first capacitor C1 includes a first electrode E1, a second electrode E2, and a third electrode E3 that overlap each other on a plane (i.e., in a plan view or in the thickness direction). In FIG. 7, the first electrode E1 and the second electrode E2 having a same area and a same shape as each other on a plane are illustrated as an example. However, the invention is not limited to this embodiment. The third electrode E3 may be disposed inside the first electrode E1 and the second electrode E2 on a plane. However, the invention is not limited to this embodiment. The edge of the third electrode E3 may be aligned with the edge of the first electrode E1 on a plane.

In FIG. 7, a seventh insulating layer I7 including a first portion P1 and a second portion P2 is illustrated, and a sixth insulating layer I6 and an eighth insulating layer I8 are not illustrated. The first portion P1 and the second portion P2 are arranged to be spaced apart from each other with a second contact region CH2 interposed therebetween in a first direction DR1. FIG. 7 illustrates only a portion of one pixel PX illustrated in FIG. 4, and the seventh insulating layer I7 may be disposed over the entire display region AA illustrated in FIG. 4. The seventh insulating layer I7 may include a first portion P1 and a second portion P2 disposed for each pixel PX. The first portion P1 and the second portion P2 may be different portions of the seventh insulating layer I7 disposed over the entire display region AA and may be connected to each other through a region that is not illustrated in FIG. 7.

Referring to FIG. 8, the first electrode E1 is disposed on the sixth insulating layer I6. The sixth insulating layer I6 may include an organic material. The sixth insulating layer I6 may include a photosensitive polyimide (PSPI)-based resin, a polysiloxane-based resin, a polyhedral oligomeric silsesquioxanes (POSS)-based resin, or an acrylic-based resin.

The first electrode E1 may have a single-layer structure or a multi-layer structure in which layers are stacked along a third direction DR3. Here, the third direction DR3 may be a thickness direction of the display panel DP. The first electrode E1 having a multi-layer structure may include at least two metal layers. The conductive pattern having a multi-layer structure may include metal layers including different metals. In an embodiment, the first electrode E1 may include a titanium layer, an aluminum layer, and a titanium layer that are stacked in sequence. The second electrode E2 and the third electrode E3 to be described later may also have a single-layer or multi-layer structure. The second electrode E2 and the third electrode E3 may also include a titanium layer, an aluminum layer, and a titanium layer that are stacked in sequence.

The first electrode E1 may be electrically connected to a pattern disposed below the sixth insulating layer I6 through a first contact region CH1 defined through the sixth insulating layer I6. The “pattern disposed below” may be a conductive pattern or a semiconductor pattern. For example, the “pattern disposed below” may be a conductive pattern CP disposed on a fifth insulating layer I5 of FIG. 6. Hereinafter, the conductive pattern connected to the first electrode E1 through the first contact region CH1 and disposed below the sixth insulating layer I6 is defined as a first conductive pattern CP1 (see FIG. 8).

In FIG. 8, an embodiment including a hole-type first contact region CH1 is illustrated as an example. The first contact region CH1 of a hole type may electrically connect different conductive patterns to each other within a narrow region.

The first electrode E1 may include a first edge ED1 and a second edge ED2 opposite to each other in the first direction DR1. The first contact region CH1 is disposed to be closer to the first edge ED1 than to the second edge ED2 in the first direction DR1.

Referring to FIG. 8, the seventh insulating layer I7 is disposed on the sixth insulating layer I6 and covers the first electrode E1. The seventh insulating layer I7 may include an organic material. The seventh insulating layer I7 may include a photosensitive polyimide (PSPI)-based resin, a polysiloxane-based resin, a polyhedral oligomeric silsesquioxanes (POSS)-based resin, or an acrylic-based resin.

The first portion P1 and the second portion P2 are spaced apart from each other in the first direction DR1 and define a second contact region CH2 having a slit shape. The second contact region CH2 does not overlap the first contact region CH1 on a plane or in the third direction DR3. The second contact region CH2 exposes a portion of the first electrode E1 disposed therebelow, that is, a contact portion E1-C.

When the first portion P1 and the second portion P2 are connected to each other, the second contact region CH2 may have a groove shape. The second contact region CH2 is disposed to be closer to the first edge ED1 than to the second edge ED2 in the first direction DR1. The length of the second contact region CH2 in a second direction DR2 may be greater than the length of each of the first electrode E1 and the second electrode E2 in the second direction DR2.

The distance between the second contact region CH2 and the first edge ED1 is shorter than the distance between the first contact region CH1 and the first edge ED1. In this embodiment, the second contact region CH2 having a larger area than the first contact region CH1 is illustrated as an example, but the embodiment of the invention is not limited thereto.

The seventh insulating layer I7 is disposed inside the first contact region CH1. The second portion P2 provides a flat upper surface for the second electrode E2, excluding the second contact region CH2. As described later, even though the second electrode E2 overlaps the first contact region CH1, the second electrode E2 may be flat on the first contact region CH1, just like in other regions.

Referring to FIG. 8, the patterned second portion P2 may provide an inclined surface ICS while covering the second edge ED2 of the first electrode E1. The function of the inclined surface ICS will be described later.

The second electrode E2 is disposed on the seventh insulating layer I7. The second electrode E2 is disposed on at least the second portion P2. A first edge ED10 and a second edge ED20 of the second electrode E2 are formed to respectively align with the first edge ED1 and the second edge ED2 of the first electrode E1. In an embodiment, the first edge ED10 and the second edge ED20 of the second electrode E2 may overlap the first edge ED1 and the second edge ED2 of the first electrode E1, respectively, on a plane. However, the invention is not limited to this embodiment.

The second electrode E2 is electrically connected to the first electrode E1 through the second contact region CH2. Accordingly, the first electrode E1 and the second electrode E2 electrically connected to each other may collectively define one of the two electrodes (or two conductive plates) of the first capacitor C1, which face each other.

The eighth insulating layer I8 covering the second electrode E2 is disposed on the seventh insulating layer I7. The eighth insulating layer I8 may include an inorganic material. The eighth insulating layer I8 may include silicon oxide, silicon oxynitride, or silicon nitride and may have a single-layer or multi-layer structure. The eighth insulating layer I8 has a smaller thickness than organic layers below, that is, the sixth insulating layer I6 and the seventh insulating layer I7. In an embodiment, the eighth insulating layer I8 may include silicon nitride having a thickness of about 400 angstrom (Å) to about 600 Å.

In an embodiment, a portion of the eighth insulating layer I8 may come in contact with the sixth insulating layer I6 through a region in which the seventh insulating layer I7 is not disposed. In such an embodiment, the inclined surface ICS of the seventh insulating layer I7 described above functions as a buffer structure with respect to the eighth insulating layer I8. A thin inorganic film, such as the eighth insulating layer I8, is relatively prone to cracking in a region with abrupt changes in shape, but the inclined surface ICS of the seventh insulating layer I7 may effectively prevent such abrupt shape changes in the eighth insulating layer I8. Accordingly, even though the eighth insulating layer I8 including the second edge ED20 extends to the side surface and the inclined surface ICS of the second electrode E2, cracks in the eighth insulating layer I8 may be reduced.

FIG. 8 illustrates an embodiment where the inclined surface ICS starts from the second edge ED20 and is inclined toward the upper surface of the sixth insulating layer I6. Without being limited thereto, however, the upper surface of the second portion P2 may be further disposed to the right side of the second edge ED20. In addition, the inclined surface ICS may be inclined from the end of the upper surface of the second portion P2 toward the upper surface of the sixth insulating layer I6.

In addition, it is desired that the second electrode E2 has a relatively thin thickness to suppress cracks in the eighth insulating layer I8, which is an inorganic film. Accordingly, in an embodiment, the second electrode E2 in contact with the eighth insulating layer I8 may have a thinner thickness than the first electrode E1 that is not in contact with the eighth insulating layer I8.

The third electrode E3 is disposed on the eighth insulating layer I8. In an embodiment, the third electrode E3 may overlap the first contact region CH1 and may not overlap the second contact region CH2. The third electrode E3 defines the other electrode of the two electrodes facing each other in the first capacitor C1. The eighth insulating layer I8, which is thinner than an organic layer and has a high dielectric constant, may correspond to the dielectric of the first capacitor C1 and increase the capacitance of the first capacitor C1.

In a case where the third electrode E3 is omitted and the second electrode E2 is not electrically connected to the first electrode E1, the first electrode E1 and the second electrode E2 define the two electrodes facing each other in the first capacitor, and since the seventh insulating layer I7, which is an organic layer, has a large thickness and a low dielectric constant, the capacitance is reduced.

In addition, in a case where the seventh insulating layer I7, which is an inorganic layer, is applied, the first contact region CH1 may not be filled in a planar manner and thus the second electrode E2 may not be allowed to overlap the first contact region CH1. As a result, the area of the second electrode E2 is inevitably reduced, which in turn decreases the capacitance.

In an embodiment, to effectively prevent such capacitance reduction described above, only the first contact region CH1 may be filled with an organic material, and an inorganic layer may be formed thereon. The inorganic layer may simultaneously come in contact with the first electrode E1 and the organic material filled in the first contact region CH1. In order to fill only the first contact region CH1 with an organic material, an organic layer may be desired to be formed of the organic material and then patterned by an ashing process. Such a process may cause process deviations between the pixels PX, or defects such as increased surface roughness of the organic material or oxidation of the first electrode. However, the first capacitor C1 according to an embodiment described with reference to FIGS. 7 and 8 may have increased capacitance and simultaneously suppress process variations and defects caused by an ashing process. Based on the same pixel region, the area of the third electrode E3 may increase by about 20%, and the capacitance of the first capacitor C1 may be increased by about 5% to about 11% when the inorganic layer may simultaneously come in contact with the first electrode E1 and the organic material filled in the first contact region CH1.

Hereinafter, an embodiment of a method for manufacturing a first capacitor C1 will be described. After forming a sixth insulating layer I6, the planarization process of the sixth insulating layer I6 may be performed. Thereafter, through an exposure and development process, a first contact region CH1 may be formed in the sixth insulating layer I6.

Next, a first electrode E1 is formed on the sixth insulating layer I6 through a photolithography process. In addition, a seventh insulating layer I7 is formed on the sixth insulating layer I6, and the seventh insulating layer I7 is patterned through an exposure and development process. The seventh insulating layer I7 may partially expose the sixth insulating layer I6. That is, a second contact region CH2 may be formed in the seventh insulating layer I7.

The seventh insulating layer I7 may fill the first contact region CH1 formed on the sixth insulating layer I6. Since the seventh insulating layer I7 includes an organic material, it may provide a relatively flat upper surface even though the first contact region CH1 is disposed therebelow.

A second electrode E2 is formed on the seventh insulating layer I7 through a photolithography process. The second electrode E2 and the first electrode E1 are connected to each other through the second contact region CH2 formed in the seventh insulating layer I7.

An eighth insulating layer I8 covering the second electrode E2 is formed above the sixth insulating layer I6 and the seventh insulating layer I7. An inorganic material may be deposited to form the eighth insulating layer I8. The eighth insulating layer I8 may come in contact with the sixth insulating layer I6 in a region in which the seventh insulating layer I7 is not disposed.

A third electrode E3 is formed on the eighth insulating layer I8 through a photolithography process. Accordingly, the first capacitor C1 may be formed or defined between the second electrode E2 and the third electrode E3.

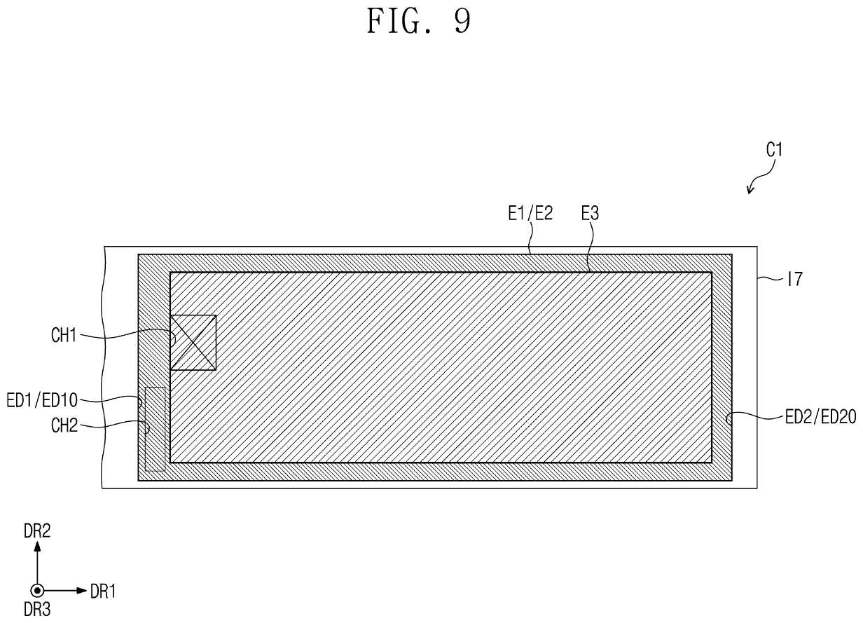

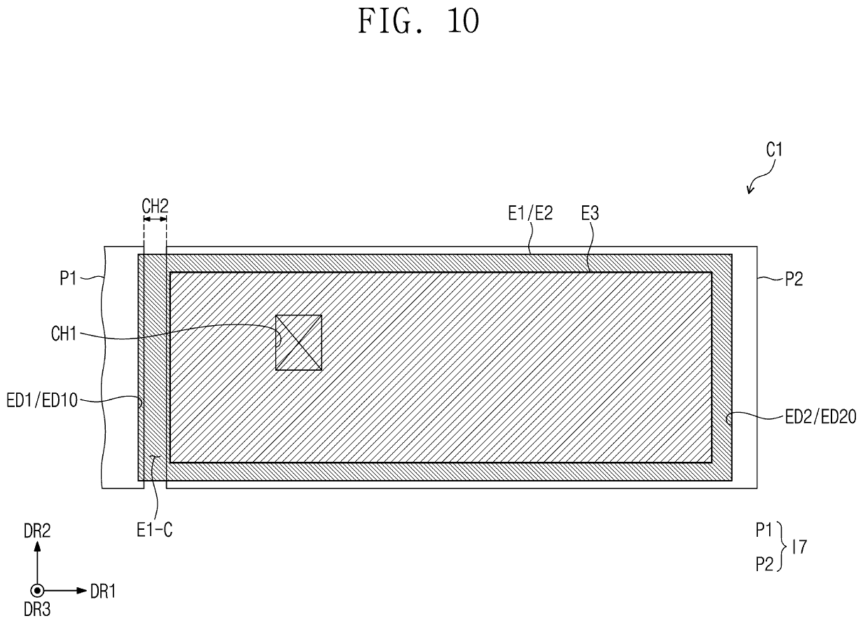

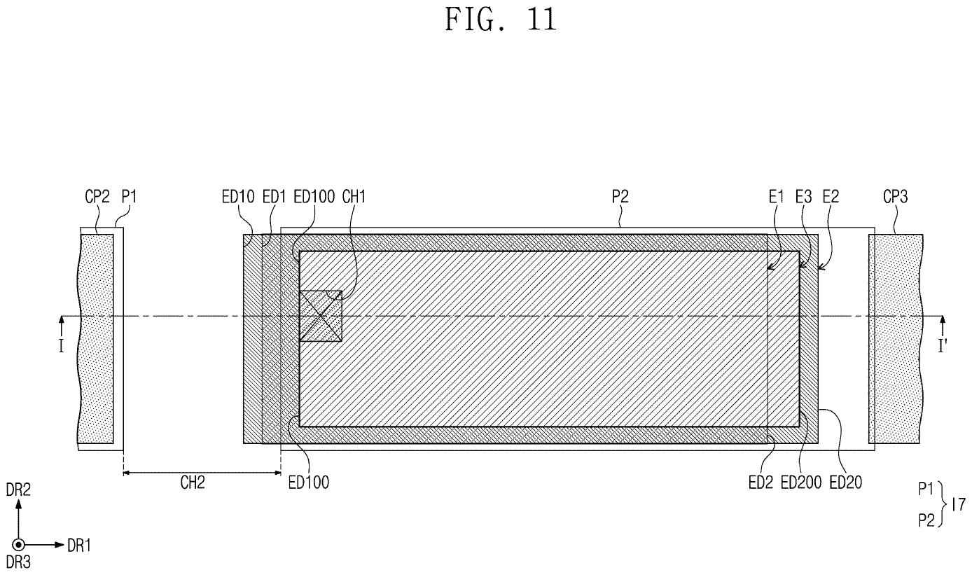

FIGS. 9 and 10 are plan views of the first capacitor C1 according to an embodiment of the invention. The same or like elements shown in FIGS. 9 and 10 as those described above with reference to FIGS. 7 and 8 are labeled with the same reference characters, and any repetitive detailed description thereof will hereinafter be omitted or simplified.

Referring to FIG. 9, in another embodiment, the shape of the seventh insulating layer I7 may be changed or modified. Unlike the seventh insulating layer I7 including the first portion P1 and the second portion P2 of FIG. 7, an integrally formed seventh insulating layer I7 is illustrated in FIG. 9 as an example.

The area of the second contact region CH2 may be reduced. The second contact region CH2 of a hole type is illustrated as an example. The planar shape of the second contact region CH2 is not particularly limited. The areas and shapes of the second contact region CH2 and the first contact region CH1 may be different from each other. As described above, the second contact region CH2 may be implemented in various ways, so that the design freedom of the first capacitor C1 may be improved.

Referring to FIG. 10, in another embodiment, the position of the first contact region CH1 has moved to the right side, compared to FIG. 7. As described with reference to FIG. 8, since the first electrode E1 and the second electrode E2 may be disposed on the first contact region CH1, the position of the first contact region CH1 is not limited. Therefore, the design freedom of the first capacitor C1 may be improved.

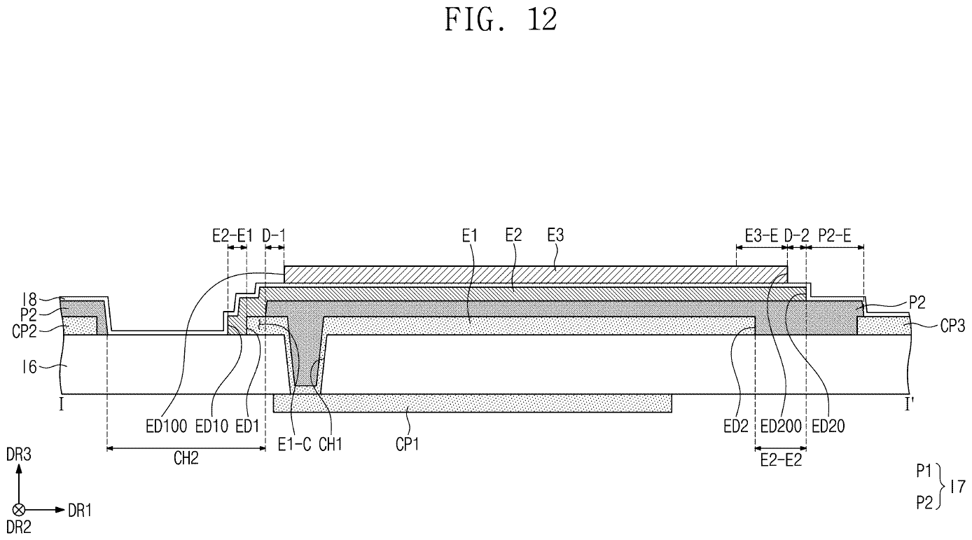

FIG. 11 is a plan view of the first capacitor C1 according to an embodiment of the invention. FIG. 12 is a cross-sectional view of the first capacitor C1 according to an embodiment of the invention. The same or like elements shown in FIGS. 11 and 12 as those described above with reference to FIG. 7 to 10 are labeled with the same reference characters, and any repetitive detailed description thereof will hereinafter be omitted or simplified.

In an embodiment, a first electrode E1 is disposed on the sixth insulating layer I6. The first electrode E1 may be substantially the same as the first electrode E1 described with reference to FIGS. 6 to 9.

Conductive patterns spaced apart from the first electrode E1 are disposed on the sixth insulating layer I6. In FIGS. 10 and 11, embodiments where a second conductive pattern CP2 and a third conductive pattern CP3 are disposed on both opposing sides of the first electrode E1 are illustrated as an example. The second conductive pattern CP2 and the third conductive pattern CP3 may be a signal line or a connection electrode of a corresponding pixel, or may be a first electrode, a signal line, or a connection electrode of an adjacent pixel.

Since the first electrode E1, the second conductive pattern CP2, and the third conductive pattern CP3 are disposed on the sixth insulating layer I6, there is a limitation on the design of the first electrode E1. That is, the area of the first electrode E1 may be limited to prevent interference with the second conductive pattern CP2 and the third conductive pattern CP3.

A seventh insulating layer I7 is disposed on the sixth insulating layer I6. The seventh insulating layer I7 may cover at least a portion of the first electrode E1, a portion or all of the second conductive pattern CP2, and a portion or all of the third conductive pattern CP3. FIGS. 11 and 12 illustrate embodiments where the seventh insulating layer I7 includes a first portion P1 and a second portion P2.

A region in which the first portion P1 and the second portion P2 are spaced apart from each other is defined as a second contact region CH2. The second contact region CH2 exposes a portion of the upper surface of the sixth insulating layer I6 and a first edge ED1 of the first electrode E1.

The second contact region CH2 of FIGS. 11 and 12 has a larger area or a larger width than the second contact region CH2 illustrated in FIG. 7. The width may be measured in the first direction DR1. The width of the second contact region CH2 may be formed to match a design value or may be determined by the material of the seventh insulating layer I7.

In an embodiment of the invention, when the second contact region CH2 is formed in the seventh insulating layer I7 including or made of a typical organic material by a photolithography process, the removal area of the seventh insulating layer I7 is determined according to the design value of photoresist. In an embodiment of the invention, when the second contact region CH2 is formed in the seventh insulating layer I7 including or made of photosensitive polyimide by an exposure and development process, the width of the second contact region CH2 may be determined according to the development characteristics of the photosensitive polyimide.

The first portion P1 may cover the second conductive pattern CP2. The second portion P2 may cover the first electrode E1, but may expose a portion thereof. The exposed portion of the first electrode E1 may be defined as a contact portion E1-C, and the contact portion E1-C may include a first edge ED1. The second portion P2 covers at least a portion of the third conductive pattern CP3. The second portion P2 may be disposed between the first electrode E1 and the third conductive pattern CP3. A portion of the second portion P2 is disposed in a region, in which the first electrode E1 and the third conductive pattern CP3 are spaced apart from each other, and contacts the sixth insulating layer I6 in the region. A portion of the second portion P2 includes an extension portion P2-E to be described later.

A second electrode E2 is disposed on the second portion P2. A portion of the second electrode E2 may come in contact with the contact portion E1-C. A first extension portion E2-E1 (or first expansion portion) of the second electrode E2 may be disposed in the second contact region CH2, surround the first edge ED1, and come in contact with the upper surface of the sixth insulating layer I6. The second electrode E2 according to this embodiment extends to one side thereof by the length of the first extension portion E2-E1 beyond the second electrode E2 of FIG. 8.

A portion of the second electrode E2 disposed on the sixth insulating layer I6 within a region in which the first electrode E1 and the third conductive pattern CP3 are spaced apart from each other may be defined as a second extension portion E2-E2. The second extension portion E2-E2 is disposed on the seven insulating layer I7. The second electrode E2 according to an embodiment extends to the other side thereof by the length of the second extension portion E2-E2 beyond the second electrode E2 of FIG. 8. The second extension portion E2-E2 increases the capacitance of the first capacitor C1. The second extension portion E2-E2 is supported by a portion of the second portion P2 disposed in a region in which the first electrode E1 and the third conductive pattern CP3 are spaced apart from each other.

A portion that does not overlap the second extension portion E2-E2 and further extends toward the third conductive pattern CP3 may be defined as an extension portion P2-E of the second portion P2. As the extension portion P2-E of the second portion P2 is disposed, the second extension portion E2-E2 and the third conductive pattern CP3 may be effectively insulated from each other. That is, the extension portion P2-E of the second portion P2 may prevent a short circuit between the second extension portion E2-E2 and the third conductive pattern CP3.

An eighth insulating layer I8 is disposed on the second electrode E2. The eighth insulating layer I8 may come in contact with a portion of the upper surface of the sixth insulating layer I6 within the second contact region CH2. The eighth insulating layer I8 is disposed on the second electrode E2 and the seventh insulating layer I7.

In an embodiment, the eighth insulating layer I8 covers the second extension portion E2-E2 of the second electrode E2, the extension portion P2-E of the second portion P2, and the third conductive pattern CP3. Since the second extension portion E2-E2 of the second electrode E2, the extension portion P2-E of the second portion P2, and the third conductive pattern CP3 form a cross section that gradually decreases in height, abrupt shape changes in the eighth insulating layer I8 may be prevented, thereby reducing cracks in the eighth insulating layer I8.

A third electrode E3 is disposed on the eighth insulating layer I8. The third electrode E3 is disposed inside the second electrode E2 on a plane. A first edge ED100 of the third electrode E3 may be spaced apart from a first end of the second portion P2 by a first distance D-1. A second edge ED200 of the third electrode E3 may be spaced apart from a second edge ED20 of the second electrode E2 by a second distance D-2.

The first distance D-1 and the second distance D-2 may be conditions for the third electrode E3 to be disposed within the flat region of the eighth insulating layer I8. When the first distance D-1 is eliminated (i.e., becomes substantially close to zero) and the third electrode E3 extends further toward the second contact region CH2, or when the second distance D-2 is eliminated and the third electrode E3 extends further toward the extension portion P2-E of the second portion P2, defects (short circuits between the electrodes) may occur due to the step difference of the eighth insulating layer I8 disposed therebelow. In addition, the first distance D-1 and the second distance D-2 are set so that uniform third electrodes E3 are formed in pixel regions in consideration of process errors between the pixel regions. The sizes of the first distance D-1 and the second distance D-2 may be determined in consideration of the process capability (or process quality) of a photolithography process used to form the third electrode E3.

Referring to FIGS. 10 and 11, the seventh insulating layer I7 having a large critical dimension (CD) is patterned to form the extension portion P2-E of the second portion P2, and as a result, a region is secured for disposing the second extension portion E2-E2, which is insulated from the third conductive pattern CP3 and in which the second electrode E2 extends. An extension portion E3-E of the third electrode E3 is also disposed on the second extension portion E2-E2 of the second electrode E2, and as a result, a region in which the second extension portion E2-E2 and the extension portion E3-E of the third electrode E3 are disposed is secured by the extension portion P2-E of the second portion P2. As a result, the areas of the second electrode E2 and the third electrode E3 increase compared to the embodiments of FIGS. 7 and 8, and the capacitance of the first capacitor C1 may be increased.

According to an embodiment of the invention, the overlapping area between the electrodes of the capacitor may increase such that the capacitance of the capacitor may be increased.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a base layer;
a plurality of insulating layers disposed above the base layer;
a plurality of conductive patterns disposed above the base layer;
a capacitor disposed above the base layer;
a transistor disposed above the base layer; and
a light-emitting element disposed above the base layer,
wherein:
the plurality of insulating layers comprises a first insulating layer including an organic material, a second insulating layer disposed on the first insulating layer and including an organic material, and a third insulating layer disposed on the second insulating layer and including an inorganic material; and
the capacitor comprises a first electrode disposed between the first insulating layer and the second insulating layer and connected to a pattern disposed below the first insulating layer through a first contact region defined through the first insulating layer, a second electrode disposed between the second insulating layer and the third insulating layer and connected to the first electrode through a second contact region exposing a contact portion of the first electrode, and a third electrode disposed on the third insulating layer, facing the second electrode, and overlapping the first contact region and not overlapping the second contact region in a plan view,
wherein, in the plan view:
the first contact region and the second contact region do not overlap each other; and
the second insulating layer fills the first contact region.

2. The display device of claim 1, wherein:
the first electrode comprises a first edge and a second edge which are opposite to each other in a first direction;
in the plan view, each of the second contact region and the first contact region is closer to the first edge than to the second edge; and
in the plan view, a distance between the second contact region and the first edge is shorter than a distance between the first contact region and the first edge.

3. The display device of claim 1, wherein, in the plan view, the third electrode is disposed inside the second electrode.

4. The display device of claim 1, wherein the second electrode has a thickness smaller than a thickness of the first electrode.

5. The display device of claim 4, wherein the first electrode and the second electrode have substantially a same planar area as each other.

6. The display device of claim 1, wherein:
the second electrode comprises a first edge and a second edge which are opposite to each other in a first direction;
the second contact region extends in a second direction orthogonal to the first direction; and
a length of the second contact region in the second direction is greater than a length of the second electrode in the second direction.

7. The display device of claim 1, wherein the organic material of the second insulating layer comprises at least one selected from a photosensitive polyimide (PSPI)-based resin, a polysiloxane-based resin, a polyhedral oligomeric silsesquioxanes (POSS)-based resin, or an acrylic-based resin.

8. The display device of claim 1, wherein:
the first electrode comprises a first edge and a second edge which are opposite to each other in a first direction; and
the second insulating layer comprises a first portion and a second portion, which face each other in the first direction, with the second contact region interposed therebetween.

9. The display device of claim 1, wherein:
the second electrode comprises a first edge and a second edge which are opposite to each other in a first direction;
the second insulating layer includes an inclined surface inclined from the second edge toward an upper surface of the first insulating layer; and
the third insulating layer covers the second edge of the second electrode, the inclined surface, and the upper surface of the first insulating layer.

10. The display device of claim 1, wherein:
the first electrode comprises a first edge and a second edge which are opposite to each other in a first direction; and
the pattern comprises a first conductive pattern among the plurality of conductive patterns,
wherein:
the plurality of conductive patterns comprise a second conductive pattern spaced apart from the first edge of the first electrode and a third conductive pattern spaced apart from the second edge of the first electrode;
the second insulating layer overlaps the second conductive pattern and the third conductive pattern in the plan view;
the second contact region exposes the first edge of the first electrode; and
the second electrode covers the contact portion and the first edge of the first electrode and contacts an upper surface of the first insulating layer.

11. The display device of claim 10, wherein:
the second contact region exposes a portion of an upper surface of the first insulating layer; and
the third insulating layer contacts the portion of the upper surface of the first insulating layer through the second contact region.

12. The display device of claim 10, wherein:
a portion of the second insulating layer is disposed between the first electrode and the third conductive pattern; and
a portion of the second electrode is disposed on the second insulating layer in a region between the first electrode and the third conductive pattern.

13. The display device of claim 12, wherein:
the third insulating layer is disposed on the portion of the second electrode and the portion of the second insulating layer; and
a portion of the third electrode is disposed on the portion of the second electrode.

14. The display device of claim 1, wherein the transistor outputs a data voltage to the capacitor.

15. The display device of claim 1, wherein the third insulating layer has a thickness smaller than a thickness of the first insulating layer and a thickness of the second insulating layer.

16. An electronic device comprising:
a display device; and
a processor which controls the display device,
wherein the display device comprises:
a base layer;
a plurality of insulating layers disposed above the base layer;
a plurality of conductive patterns disposed above the base layer;
a capacitor disposed above the base layer;
a transistor disposed above the base layer; and
a light-emitting element disposed above the base layer,
wherein:
the plurality of insulating layers comprise a first insulating layer including an organic material, a second insulating layer disposed on the first insulating layer and including an organic material, and a third insulating layer disposed on the second insulating layer and including an inorganic material; and
the capacitor comprises a first electrode disposed between the first insulating layer and the second insulating layer and connected to a pattern disposed below the first insulating layer among the plurality of conductive patterns through a first contact region defined through the first insulating layer, a second electrode disposed between the second insulating layer and the third insulating layer and connected to the first electrode through a second contact region exposing a contact portion of the first electrode, and a third electrode disposed on the third insulating layer, facing the second electrode, and overlapping the first contact region and not overlapping the second contact region in a plan view,
wherein, in the plan view:
the first contact region and the second contact region do not overlap each other; and
the second insulating layer fills the first contact region.

17. The electronic device of claim 16, wherein the electronic device is a virtual reality (VR) device.

18. The electronic device of claim 16, wherein:
the second electrode has a thickness smaller than a thickness of the first electrode; and
the third insulating layer has a thickness smaller than a thickness of the first insulating layer and a thickness of the second insulating layer.

19. The electronic device of claim 16, wherein the organic material of the second insulating layer comprises at least one selected from a photosensitive polyimide (PSPI)-based resin, a polysiloxane-based resin, a polyhedral oligomeric silsesquioxanes (POSS)-based resin, or an acrylic-based resin.

20. The electronic device of claim 16, wherein:
the first electrode comprises a first edge and a second edge which are opposite to each other in a first direction; and
the pattern connected to the first electrode comprises a first conductive pattern among the plurality of conductive patterns,
wherein:
the plurality of conductive patterns comprise a second conductive pattern spaced apart from the first edge of the first electrode and a third conductive pattern spaced apart from the second edge of the first electrode;
the second insulating layer overlaps the second conductive pattern and the third conductive pattern in the plan view;
the second contact region exposes the first edge of the first electrode; and
the second electrode covers the contact portion and the first edge of the first electrode and contacts an upper surface of the first insulating layer.
